(19) United States
(12) Patent Application Publication
(10) Pub. No.: US 2026/0290988 A1
(43) Pub. Date: Sep. 24, 2026

(54) SYSTEM AND METHOD FOR LOWERING ELECTROMAGNETIC EMISSIONS RADIATED INSIDE ENERGY STORAGE ENCLOSURES

(71) Applicant: FLUENCE ENERGY, LLC, Arlington, VA (US)

(72) Inventors: Adam J. BOWER, Arlington, VA (US); Atul PATHAK, Arlington, VA (US); Wells Case JACOBSON, JR., Arlington, VA (US); Nitin SINGHAL, Arlington, VA (US)

(73) Assignee: FLUENCE ENERGY, LLC, Arlington, VA (US)

(21) Appl. No.: 18/873,136

(22) PCT Filed: Sep. 27, 2024
(86) PCT No.: PCT/US2024/048788

§ 371 Date: Dec. 9, 2024

Related U.S. Application Data
(60) Provisional application No. 63/541,128, filed on Sep. 28, 2023.

(51) Int. Cl. H01M 50/298; H01M 50/251; H01M 50/507; H05K 9/00

(52) U.S. Cl. CPC H01M 50/298; H01M 50/251; H01M 50/507; H05K 9/0009; H05K 9/0018; H05K 9/0071; H01M 2220/10

(57) ABSTRACT

An energy storage node includes a plurality of battery modules arranged within the energy storage node and a shielding wire. Each battery module includes a plurality of sub-module assemblies having a direct current supplied via the shielding wire. The direct current enters a first battery module at a first end of the first battery module, and the shielding wire traverses a width of the first battery module such that the direct current enters a first battery cell of a first sub-module assembly. The direct current flows through the first sub-module assembly in a direction opposite from the first battery cell and through next adjacent battery cells of the first battery module. Upon exiting a last of the sub-module assemblies, the shielding wire is twisted at least one with a portion of the shielding wire located along the first traverse of the width of the first battery module.

### CROSS-REFERENCE TO RELATED APPLICATION

This application claims priority to U.S. Provisional Patent Application No. 63/541,128, filed on Sep. 28, 2023, titled “System and Method for Lowering Electromagnetic Emissions Radiated Inside Energy Storage Enclosures”, the entire disclosure of which is incorporated by reference herein.

### TECHNICAL FIELD

The present subject matter relates to examples of system and methods for reducing electromagnetic emissions within an energy storage system by reducing loop diameter via strategic wire twists.

### BACKGROUND

Energy storage systems, such battery energy storage systems (BESS), compound energy storage systems, as well as some energy provisioning systems, are often made up of large nodes purpose-built to create, store, and provision electrical energy. Consequently, these nodes are designed to be as efficient as possible at performing the tasks of creating, storing, or provisioning energy, to the exclusion of many other concerns. Efficiency can come in the form of minimizing electrical cabling within the system, as any extraneous length of cabling introduces additional resistance into the node, which further causes more useless heat to be generated, which must be ventilated or processed. Efficiency can also come in the form of computing hardware and software operating the components of the node, and applying system adjustments on a sub-second basis to maximize the performance of the node.

Computed adjustments to an energy storage node on a sub-second basis require on-board computing components to the node, or at minimum on-board sensors on the energy storage node which communicate with an external computing device. However, sensitive electronics or sensors inside the enclosure of energy storage nodes will malfunction if those sensitive electronics have insufficient electromagnetic noise immunity in an electromagnetically noisy environment. The enclosure of a conventional energy storage node is an electromagnetically noisy environment. The power conversion system (PCS) within or coupled to the node injects high noise content onto the massive direct current circuit of the node, thereby causing large, radiated emissions from this direct current circuit inside the energy storage node enclosure. High common mode voltage content on the massive direct current circuit can be the source of noise that, if not controlled, will cause energy storage node communication malfunction. The noise present on the massive direct current circuit is radiated everywhere inside the energy storage node enclosure. Traditionally, the solution to electromagnetic noise within the energy storage node is to reduce the noise on the direct current circuit by changing the PCS design or performance, which reduces the overall performance of the battery energy storage system, energy storage system, or energy provisioning system.

### SUMMARY

Hence, there is a need for systems and methods for reducing electromagnetic emissions radiated within energy systems. The electromagnetic emission reduction technologies disclosed herein reduce the wavelength of radiated emissions by reducing the diameter of the electrical loop within the energy storage nodes. The strength of noisy electromagnetic emissions is correlated to the wavelength of the radiated emissions, and the wavelength of the radiated emissions is correlated to the diameter of electrical loops within the energy storage node. Conventional energy storage nodes form one large electrical loop, running down sequentially through the battery modules of a battery rack, then continuing immediately back up to the top battery module. The large electrical loop functions like a large loop antenna, radiating a large amount of electromagnetic radiation. Functionally dividing the large loop antenna into smaller loop antennae will cause the smaller loop antennae to each radiate smaller amounts of electromagnetic radiation. The amount and/or effect of the sum of each smaller amount of radiation is less than the amount and/or effect of the large amount of electromagnetic radiation. Therefore, dividing the large electrical loop of the energy storage node into smaller electrical loops will reduce the amount and/or effect of the electromagnetic radiation within the enclosure of the energy storage node, which is a reduction of electromagnetic noise. A reduction in electromagnetic noise will allow or prolong performance of sensitive electronics with relatively low electromagnetic noise immunity.

In a first example, an energy storage node 110A includes a plurality of battery modules 412A-N arranged within the energy storage node 11A, and a shielding wire 716. Each battery module 412A of the plurality of battery modules 412A-N includes a plurality of sub-module assemblies 1-4. A direct current supplied via the shielding wire 716 enters a first battery module 702A-H at a first end 710 of the first battery module 702A-H. The shielding wire 716 from the first end 710 first traverses a width of the first battery module 702A-H such that the direct current enters a first battery cell 13 of a first sub-module assembly 1 of the plurality of sub-module assemblies 1-4. The direct current of the shielding wire 716 flows through the first sub-module assembly 1 and through next adjacent battery cells of each of the plurality of sub-module assemblies 1-4. Upon exiting a last of the plurality of sub-module assemblies 1-4, the shielding wire 716 is arranged to second traverse the width of the first battery module 702A-H such that the shielding wire 716 is twisted at least once with a portion of the shielding wire 716 located along the first traverse of the width of the first battery module 702A-H

In a second example, a method for lowering electromagnetic emissions inside an energy storage node 110A includes, supplying, via a shielding wire 716, a direct current to a first battery module of a plurality of battery modules 412A-N arranged in the energy storage node 11A. Each battery module 412A of the plurality of battery modules 412A-N includes a plurality of sub-module assemblies 1-4. The direct current supplied via the shielding wire 716 enters a first battery module 702A-H at a first end 710 of the first battery module 702A-H and traverses a width of the first battery module 702A-H such that the direct current enters a first battery cell 13 of a first sub-module assembly 1 of the plurality of sub-module assemblies 1-4. The method further includes causing the direct current of the shielding wire 716 to flow through the first sub-module assembly 1 in a direction opposite from the first battery cell 1 of the first battery module and through next adjacent battery cells of each of the plurality of sub-module assemblies 1-4. Upon exiting a last of the plurality of sub-module assemblies 1-4, the method includes arranging the shielding wire 716 to second traverse the width of the first battery module 702A-H such that the shielding wire 716 is twisted at least once with a portion of the shielding wire 716 located along the first traverse of the width of the first battery module 702A-H.

Additional objects, advantages and novel features of the examples will be set forth in part in the description which follows, and in part will become apparent to those skilled in the art upon examination of the following and the accompanying drawings or may be learned by production or operation of the examples. The objects and advantages of the present subject matter may be realized and attained by means of the methodologies, instrumentalities and combinations particularly pointed out in the appended claims.

### BRIEF DESCRIPTION OF THE DRAWINGS

The drawing figures depict one or more implementations in accordance with the present concepts, by way of example only, not by way of limitations. In the figures, like reference numerals refer to the same or similar elements.

FIG. 1A is an isometric view of a battery energy storage system that includes multiple energy storage nodes, a central control system element, and an external grid.

FIG. 1B is an isometric view of a single energy storage node, multiple optional energy storage nodes, and an external grid.

FIG. 2 is an electrical diagram of a battery energy storage system similar to that of FIGS. 1A-B depicting information and working power flows.

FIG. 3 is a system diagram of a battery energy storage system similar to that of FIGS. 1A-B depicting step-up converter controllers and the distributed nature of a battery energy storage system.

FIG. 4 is an isometric translucent view of the energy storage node of FIG. 1B that includes a battery bank of multiple battery modules.

FIG. 5 is a general depiction of a battery pack system arranged within an energy storage node.

FIG. 6A is a depiction of a conventional battery module, and the direct current flow through the sub-module assemblies.

FIG. 6B is a depiction of the conventional battery module of FIG. 6A, with the electrical loop area shaded.

FIG. 6C is a depiction of a conventional battery rack, and the direct current flow through the battery modules.

FIG. 6D is a depiction of the conventional battery rack of FIG. 6C, with the electrical loop area shaded.

FIG. 7A illustrates an embodiment of a battery module implementing wire twists, and the direct current flow through the sub-module assemblies.

FIG. 7B illustrates the embodiment of the battery module of FIG. 7A having the separate electrical loop areas shaded.

FIG. 7C illustrates an embodiment of a battery rack implementing battery modules with wire twists, and the direct current flow through the battery modules.

FIG. 7D illustrates the embodiment of the battery rack of FIG. 7C having the separate electrical loop areas shaded.

FIG. 8 is an exploded view diagram of an embodiment of a battery module including a busbar arrangement.

FIG. 9 is a process flow for lowering electromagnetic emissions inside an energy storage node.

### PARTS LISTING

100 Battery Energy Storage System
102 Energy System
104 Power Conversion System (PCS)
105 Performance Monitoring System Element
108 Transformer
109 Energy Source
110A-N Energy Storage Nodes
111 Energy Storage Element
113 Electrical Grid
114 Distributed PCS
120 Physical Space
125 Power Bus or cabling
150 Battery Array
155A-C Battery Core
200 Battery Energy Storage System
211 Core Controller
212 Power Plant Controller
251 High Voltage (HV) Bus
252 Medium Voltage (MV) Bus
254 Point of Contact (POC)
255 Data Collection Sensors
256A-N Meter Readings
257 HV/MV Transformer
258A-X Core Transformer
259Z-X Core
260A-X MV Circuit Breaker (CB_Core)
261 HV Circuit Breaker (CB_HV)
262 Array
410A-F Battery Strings
412A-N Battery Modules
413 Battery Bank
500 Battery Pack System
700 Rack
702A-H Modules
704, 706, 712 Shaded Electrical Loop Areas
710 Module First End
716 Shielding Wire
800 Battery Module
850 Busbar
851 Busbar Cabling
890A Sub-Module Assembly 1
890B Sub-Module Assembly 2
890C Sub-Module Assembly 3
890C Sub-Module Assembly 4
899A-C Secondary Busbar
Sub-Module Assemblies 1-4
900 Method
BMS Battery Management System
APS Apparent Power System Controller
Node SDU Node Storage Dispatch Unit
MDU Market Dispatch Unit
RTAC Real Time Automation Controller
DCPM Direct Current Power Module
MSD Receptacle Manual Service Disconnect Receptacle
MSC Plug Manual Service Disconnect Plug

### DETAILED DESCRIPTION

In the following detailed description, numerous specific details are set forth by way of examples in order to provide a thorough understanding of the relevant teachings. However, it should be apparent to those skilled in the art that the present teachings may be practiced without such details. In other instances, well known methods, procedures, components, transfer functions, and/or circuitry have been described at a relatively high-level, without detail, in order to avoid unnecessarily obscuring aspects of the present teachings.

The term “coupled” as used herein refers to any logical, physical, electrical, or optical connection, link or the like by which signals or light produced or supplied by one system element are imparted to another coupled element. Unless described otherwise, coupled elements or devices are not necessarily directly connected to one another and may be separated by intermediate components, elements, or communication media that may modify, manipulate, or carry the light or signals.

Unless otherwise stated, any and all measurements, values, ratings, positions, magnitudes, sizes, angles, and other specifications that are set forth in this specification, including in the claims that follow, are approximate, not exact. Such amounts are intended to have a reasonable range that is consistent with the functions to which they relate and with what is customary in the art to which they pertain. For example, unless expressly stated otherwise, a parameter value or the like may vary by as much as ±5% or as much as ±10% from the stated amount. The terms “approximately,” “significantly,” or “substantially” means that the parameter value or the like varies up to ±25% from the stated amount.

The orientations of the battery nodes, cores, arrays, racks, elements, modules, submodules, strings, banks, or cells; associated components; circuits; and/or any complete devices, such as battery energy storage systems, combined energy storage systems, or modular energy storage systems, incorporating battery nodes, racks, elements, modules, submodules, strings, banks, or cells such as shown in any of the drawings, are given by way of example only, for illustration and discussion purposes. In operation for a particular battery energy storage application, a battery node, core, array, rack, element, module, submodule, string, bank, or cell may be oriented in any other direction suitable to the particular application of the battery energy storage system, for example upright, sideways, or any other orientation. Also, to the extent used herein, any directional term, such as left, right, front, rear, back, end, up, down, upper, lower, top, bottom, and side, are used by way of example only, and are not limiting as to direction or orientation of any energy storage system or battery nodes, racks, elements, modules, submodules, strings, banks, or cells; or component of an energy storage system or battery node, rack, element, module, submodule, string, bank, or cell examples illustrated in the accompanying drawings and discussed below.

Unless otherwise indicated, any multiplicity of components, such as energy storage nodes 110A-N, battery strings 410A-F, or battery modules 412A-N can include any number of said components, including as few as one, and are not limited by the depicted number of components. Unless otherwise indicated, any coupled electrical components can be linked in series or in parallel. In the case of energy storage nodes 110A-N or battery modules 412A-N, the component may be linked in both series and/or in parallel, depending upon the state of the switch or submodule.

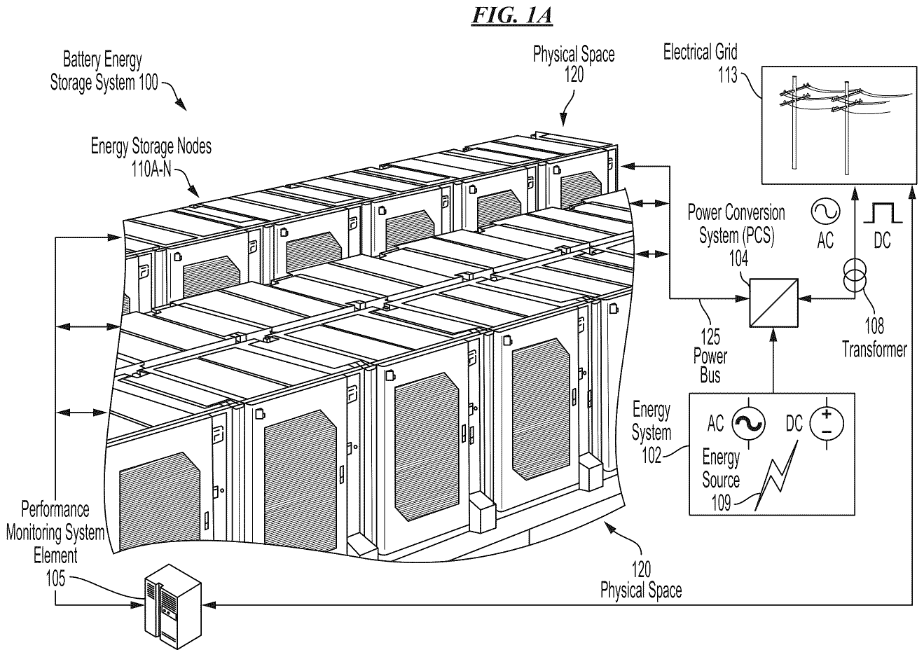

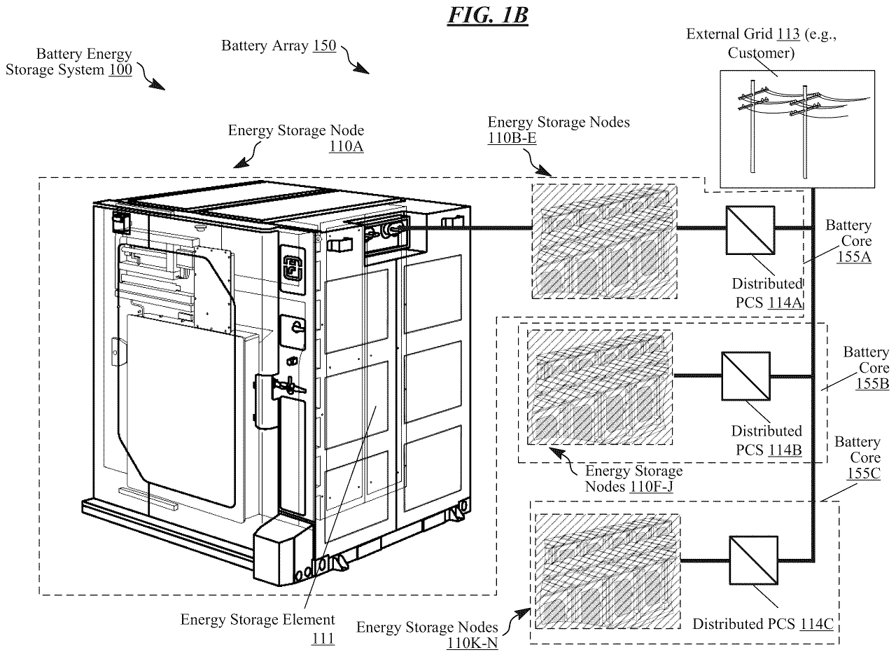

FIG. 1A is an isometric view of an energy storage system, for example, a battery energy storage system (BESS) 100 that includes multiple energy storage nodes 110A-N, a performance monitoring system element 105, an energy system 102 and an external grid 113. The BESS 100 is coupled to the energy storage system 102 and the external grid 113. The BESS 100 includes multiple energy storage nodes 110A-N optionally connected to a power conversion system (PCS) 104 and an optional transformer 108. The energy storage nodes 110A-N include batteries of any existing or future reusable battery technology including, for example, lithium ion, flow batteries, or mechanical storage such as flywheel energy storage, compressed air energy storage, pumped storage hydroelectricity, gravitational potential energy, or a hydraulic accumulator. The energy storage nodes 110A-N, collectively and individually, are capable of providing direct current electricity to an external load, such as external grid 113, and thereby discharging, as well as are capable of receiving direct current electricity from an external source, for example, energy source 109, and thereby charging. Components of the battery energy storage system 100 can be located in a physical space 120 that is outdoors or indoors, for example, inside a building, a container, or other structure.

To facilitate providing and receiving direct current, the energy storage nodes 110A-N can be connected to the power conversion element 104, for example, via a power bus or cabling 125. The power conversion system 104 is configured to standardize power inputs and outputs to and from the energy storage nodes 110A-N. The power conversion system 104 can be comprised of: (1) an inverter, converting the DC source of the energy storage nodes 110A-N to an AC waveform, and vice versa; (2) a DC/DC converter, converting the DC source of the energy storage nodes 110A-N to a different DC source characteristic; (3) other known power conversion elements; or (4) a combination thereof.

When the energy storage nodes 110A-N provide direct current, the power conversion system 104 transforms direct current into alternating current for use by the external grid 113 and normalizes the amperage from the battery modules 110A-N to the external grid 113. Additionally, when the energy storage nodes 110A-N require direct current, the power conversion system 104 transforms alternating current into direct current from the external grid 113 and normalizes the amperage from the external grid 113 to the energy storage nodes 110A-N. As shown in FIG. 1B, the energy storage nodes 110A-N are coupled in groups to a distributed power conversion system 114A-C, which may perform some or all of the tasks of a power conversion system 104 and may obviate entirely the use of a power conversion system 104.

The battery energy storage system 100 including the energy storage nodes 110A-N (and the power conversion system 104 and when the power conversion system 104 is not omitted) is depicted with a single connection to the external grid 113: in scenarios where the external grid 113 is complex and connects to multiple energy sources and connected loads, such as a power grid with consumption devices, a single connection to the battery energy storage system 100 can either absorb energy produced by the energy sources of the external grid 113 in excess of the demand of the connected loads of the external grid 113, or provide energy to the connected loads of the external grid 113 in excess of the capacity of the energy sources of the external grid 113. Alternatively, separate lines may run to a segregated energy source as well as to connected loads or the external grid 113: separate lines may be advantageous in scenarios where the segregated energy source is inconsistent, such as a wind or solar-based energy source. In such scenarios, the power from the energy source is pushed to the energy storage nodes 110A-N, which then either charge or discharge, and provide consistent energy to the connected loads or external grid 113 via another electrical route.

Energy system 102 can include any suitable system for producing electrical energy from an energy source 109. Energy system 102 can be a renewable energy system in which the energy source 109 can be replenished. Sucha a renewable energy source can include solar power, wind power, geothermal power, biomass, and hydroelectric power. For example, the renewable energy system 102 can be implemented as an array of photovoltaic modules. The photovoltaic (PV) modules can include crystalline silicon, amorphous silicon, copper indium gallium selenide (CIGS) thin film, cadmium telluride (CdTe) thin film, and concentrating photovoltaic which uses lenses and curved mirrors to focus sunlight onto small, but highly efficient, multi-junction solar cells. In another example, the energy system 102 can be a non-renewable energy system in which the energy source 109 includes a non-renewable energy source, such as a fossil fuel.

When the energy source 109 is a renewable energy source, such as solar power and wind power, it can be intermittent and less reliable compared to fossil fuels. To improve resiliency, battery energy storage system 100 can store energy from the energy system 102 when the production from the energy source 109 is high. Later on, the BESS 100 can dispatch the energy to the external grid 113 when demand is high or production from the energy source 109 is not keeping up with demand. Moreover, events may occur when a connected load or an operating demand load of the external grid 113 is excessive or there is electrical grid instability, such as during extreme weather. By storing energy from the energy source 109 and then dispatching the energy during such events, the BESS 100 can continue to dispatch a required power flow of the external grid 113.

The external grid 113 can include an electrical grid, such as a power grid or a smaller local load such as a backup power system for a facility such as a hospital, manufacturing site, residential home, or other suitable facility. The external grid 113 may deliver AC or DC power for on-grid or off-grid applications, including commercial, industrial, or residential applications. The external grid 113 may deliver power to buildings, electric vehicle charging stations, etc., including a variety of electrical loads that consume AC or DC electric power. The external grid 113 can be a front-of the meter system that is owned or operated by a utility company or a behind-the meter system that directly supplies buildings and homes with electricity.

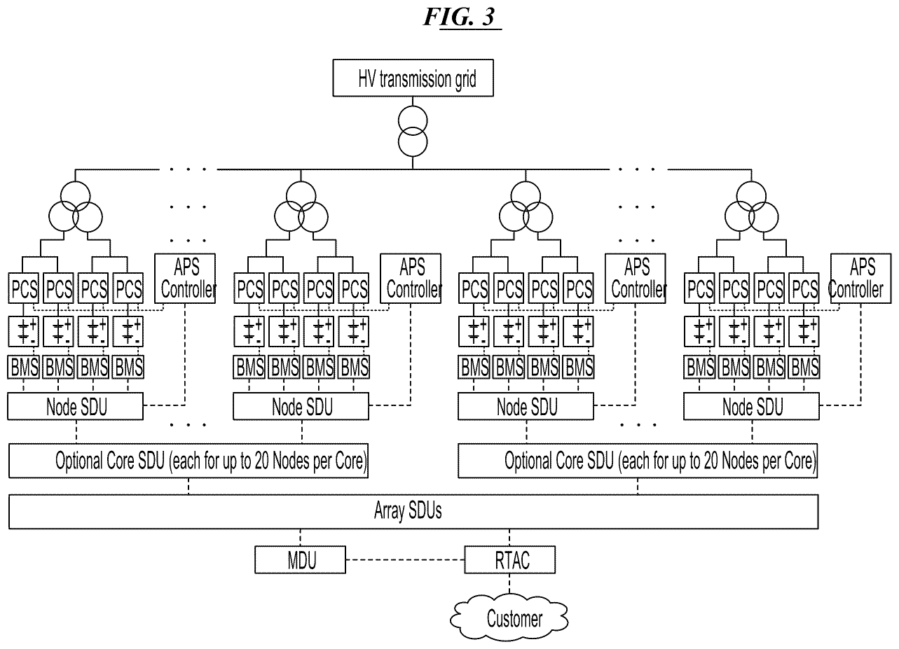

The power conversion system 104 can facilitate normalizing input or output wattage or voltage, in order to provide consistent output and protect the energy storage nodes 110A-N or external grid 113 from damage. The power conversion system 104 may perform this normalization in concert with a performance monitoring system element 105. The performance monitoring system element 105 also communicates with and controls the energy storage nodes 110A-N in order to adjust electrical output, as well as electrical capacity or intake of the energy storage nodes 110A-N. The performance monitoring system element 105 has components, such as those depicted in FIG. 3 which operate independently at their respective levels. Therefore, the performance monitoring system element 105 and the distributed control system elements (e.g., BMSs, APS controllers, SDUs, MDUs, and RTAC (see FIG. 3)) are configured to operate in a combination of independent and centralized operation.

Generally, the energy storage nodes 110A-N of the battery energy storage system 100 connected to the external grid 113 operate in concert: either providing power to the external grid 113 and discharging or receiving power from the external grid 113 and charging. This concerted effort is coordinated by performance monitoring system element 105, and other control units such as market dispatch units (MDUs) or real-time automation controllers (RTACs), not depicted here. Further methods and systems related to the management and maintenance of the energy storage nodes 110A-N (e.g., battery modules 110A-N) of the battery energy storage system 100 are disclosed in U.S. application Ser. No. 17/810,983, filed on Jul. 6, 2022, now U.S. Pat. No. 11,789,086, issued Sep. 27, 2023, titled “Cell and Rack Performance Monitoring System and Method,” the entirety of which is incorporated by reference herein.

FIG. 1B is an isometric view of an energy storage node 110A, multiple optional energy storage nodes 110B-N, and an external grid 113. The energy storage node 110A includes an energy storage element 111.

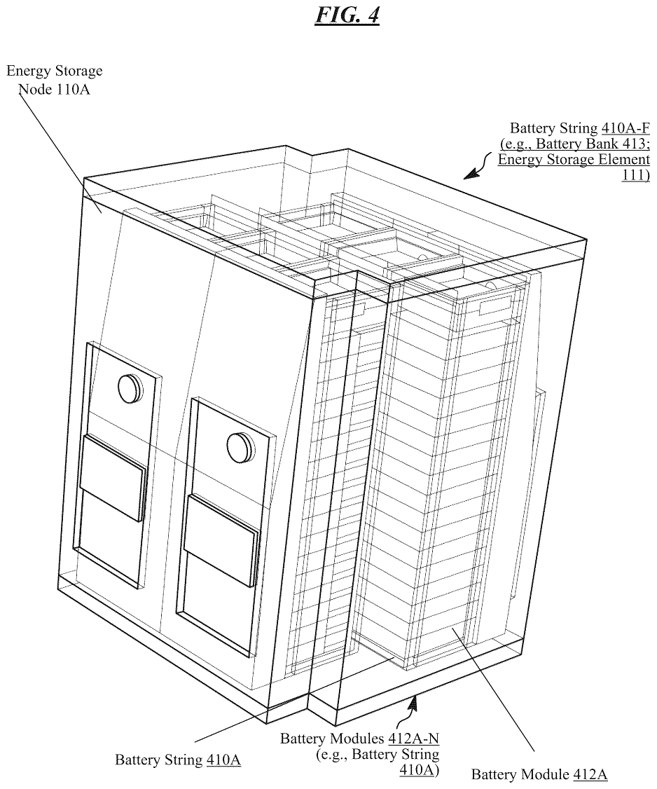

The energy storage element 111 can include: (1) a single battery cell; (2) a cell grouping, including several battery cells in parallel configuration; (3) a battery submodule or module 412A (see FIG. 4), including several battery cells in parallel and serial configuration; (4) a battery string 410A (see FIG. 4), including several battery modules 412A-N in series; (5) a battery bank 413 (see FIG. 4), including several battery strings 410A-F in parallel; (6) other known energy storage elements; or (7) a combination thereof.

The energy storage node 110A can include HVAC heating or cooling elements to regulate the temperature of the energy storage node 110A, in particular the energy storage element 111.

The energy storage nodes are organized into collections of nodes 110A-E, 110F-J, 110K-N, each collection paired with a distributed power conversion system 114A-C. A grouping of nodes 110A-E with a distributed power conversion system 114A constitutes a battery core 155A.

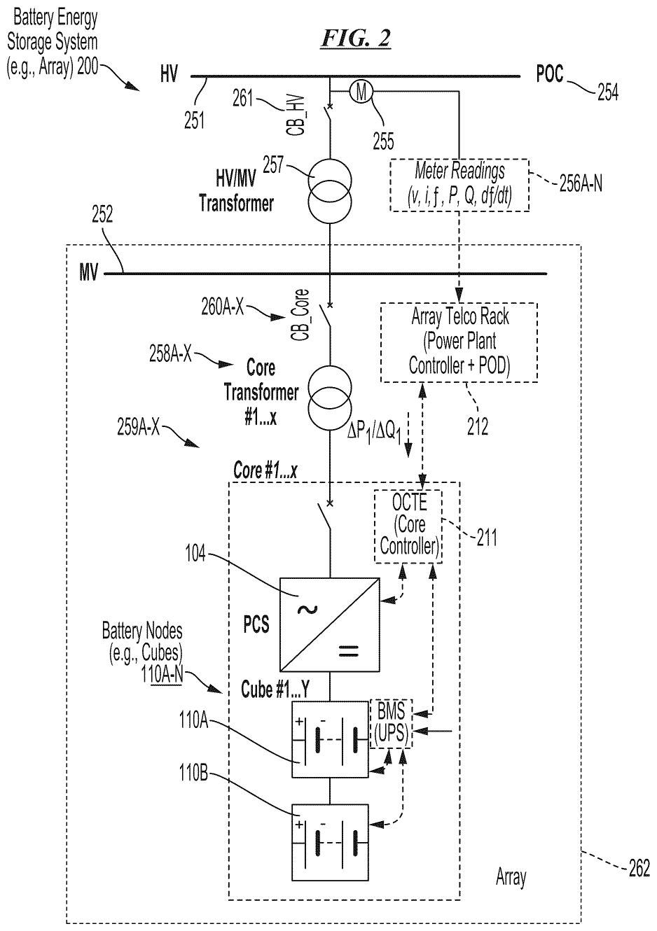

The distributed power conversion system 114A-C can include: (1) an inverter, converting the DC source of the energy storage element 111 to an AC waveform, and vice versa; (2) a DC/DC converter, converting the DC source of the energy storage element 210 to a different DC source characteristic; (3) other known power conversion elements; or (4) a combination thereof. The distributed power conversion systems 114A-C can service an individual energy storage node 110A, or any number of energy storage nodes 110A-N. Multiple energy storage nodes 110A-N are generally arranged in series, although other wiring sequences are contemplated. A distributed power conversion system 114A servicing multiple energy storage nodes 110A-E can be a battery core 255A and can be controlled by a core controller 212 (see FIG. 2). The core controller 212 can coordinate with a node controller present in each associated energy storage node 110A-E. In alternate arrangements, the distributed power conversion systems 114A-C can be integrated within the energy storage nodes 110A-N.

FIG. 2 is an electrical diagram of a battery energy storage system 200 similar to the battery energy storage system 100 of FIG. 1 depicting information and working power flows.

The battery energy storage system 200 connects to an electrical grid 113, including both an energy source 109 and a connected load, via a point of connection (POC) 254. The POC 254 is coupled to a high voltage (HV) bus 251, which is an electrical bus rated and intended for high voltage matching the voltage expected by the electrical grid. The HV bus 251 can allow for multiple battery energy storage systems 200 or power storage or generating facilities to be linked in series or in parallel before connecting to an electrical grid via the POC 254.

The battery energy storage system 200 includes an HV circuit breaker 261, designed to selectively isolate the remainder of the battery energy storage system 200 from the HV bus 251. The HV circuit breaker 261 may be hardwired to trip under certain circumstances, or the HV circuit breaker 261 may be controlled by the power plant controller 212 or other controllers.

An HV/medium voltage (MV) transformer 257 is coupled between the HV bus 251 and an MV bus 252. The HV/MV transformer steps the voltage experienced at the HV bus connection end 251 down to the voltage expected at the MV bus 252 connection end, as well as stepping up the voltage from the MV bus 252 connection end to the voltage expected at the HV bus 251 connection end.

The MV bus 252 is within the bounds of the array 262. The array 262 includes a power plant controller 212 to facilitate operation of one or more cores 259A-X. While multiple arrays 261 may be coupled in series or in parallel to the MV bus 252, in this example only a single array 262 with a single power plant controller 212 is depicted.

A core 259A is coupled to the MV bus 252 by a core transformer 258A and a core circuit breaker 260A. Multiple cores 259A-X are connected to a single MV bus 252, each with a respective core transformer 259A-X and respective core circuit breaker 260A-X: in this figure, only a single core 259A is depicted in detail.

The MV circuit breaker 260A is designed to selectively isolate the remainder of the core 259A from the MV bus 252. The MV circuit breaker 252 may be hardwired to trip under certain circumstances, or the MV circuit breaker 252 may be controlled by the power plant controller 212, the core controller 211, or other controllers.

The core transformer 258A is coupled between the MV bus 252 and the core 259A. The core transformer 258A steps the voltage experienced at the MV bus connection end 252 down to the voltage expected at the core 259A connection end, as well as stepping up the voltage from the core 259A connection end to the voltage expected at the MV bus 252 connection end.

The core 259A includes the power conversion system 104, which includes all hardware and controls to convert bi-directionally between direct current (DC) and alternating current (AC) power. The power conversion system 104 provides AC power to and from the MV bus 252, and provides DC power to and from the cubes 110A-N.

Physical data collection sensors and data logging can be used through the battery energy storage system 100, to collect operational and environmental data, in particular, voltage, current, temperature, frequency, power, or state of charge from the components of the battery energy storage system, such as the energy storage node 110A, the distributed PCSs 114A-C, the HV/MV transformers 257, core transformers 258A-X, cores 259A-X, buses 251, 252, the meter 255, and controllers 211, 212.

At least one data collection sensor, for example, a meter 255 is connected near the HV bus 251 for the purpose of collecting at least measured values relevant to oscillation determinations: instant voltage, current, as well as power frequency, instant power, and the rate of change of frequency, are all values that can inform the power plant controller 212 and the performance monitoring system element 105 in dampening power oscillations.

The meter readings 256A-N are collected continuously or periodically by the meter 255 and are provided to the power plant controller 212.

FIG. 3 is a system diagram of a battery energy storage system similar to that of FIGS. 1A-B depicting step-up converter controllers and the distributed nature of a battery energy storage system. Energy storage nodes are electrically connected to power conversion systems (PCSs), which are then electrically connected together via a bus, then electrically connected via a three-winding transformer to another bus, which then electrically connects to the HV voltage grid via a transformer. The energy storage nodes are controlled by battery management systems (BMSs), which, along with the PCSs, communicate with apparent power system controllers (APSs). The APSs and the BMSs communicate with node storage dispatch units (SDUs). Node SDUs interface with and monitor the connected BMSs, PCSs and other hardware to higher level controls. The node SDUs communicate with core SDUs, which dispatch real and reactive power to the Nodes based on their operation conditions, as well as provide telemetry values to the node SDUs, and provide the array SDU and node SDUs with core-level system operation data. The core SDUs communicate with the array SDU, which provides a market dispatch unit (MDU) and real-time automation controller (RTAC) with measurements and system operation data. The array SDU also dispatches real and reactive power to the core SDUs based on core-level stored energy. The MDU executes real and reactive power applications, while the RTAC communicates with customer control systems utilizing adjustable various interfaces.

Physical data collection sensors and data logging can be used throughout the battery energy storage system, to collect operational and environmental data from the components of the battery energy storage system, such as the energy storage nodes, PCSs, BMSs, APSs, node SDUs, core SDUs, array SDU, MDU, and RTAC. The data collected can include but is not limited to state of charge, differential voltages, or temperature of the energy storage nodes, PCSs, BMSs, APSs, node SDUs, core SDUs, array SDU, MDU, or RTAC.

FIG. 4 is an isometric translucent view of the energy storage node 110A of FIG. 1B that includes a battery bank 413 of multiple battery modules 412A-N. The energy storage node 110A stores a plurality of battery strings 410A-F as a battery bank 413 and as an energy storage element 111. The energy storage node 110A is both a physical housing of energy storage element 111, as well as a logical and electrical collection of the battery bank 413 that constitutes energy storage element 111: the energy storage node 110A physically houses the battery bank 413, and the electrical performance of the battery bank 413 comprising the energy storage element 111 may be attributed to the energy storage node 110A itself. For example, if a battery string 410A of the battery bank 413 is able to store one hundred and two kilowatt hours of energy, and the battery bank 413 contains six battery strings 410A-F, then the energy storage node 110A (as well as the energy storage element 111) may be understood to and be described as storing six hundred and twelve kilowatt hours of energy. An energy storage node 110A, energy storage element 111, and battery bank 413 may contain greater or fewer numbers of battery strings 410A-F than depicted in the figure.

A given battery string 410A contains multiple battery modules 412A-N. Much like the relationship between the energy storage node 110A and contained battery bank 413, the battery string 410A is both a physical collection of battery modules 412A-N as well as a logical and electrical collection of battery modules 412A-N. As an example, if a battery module 412A is able to store six kilowatt hours of energy, and the battery string 410A contains seventeen battery modules 412A-N, then the battery string 410A may be understood to and be described as storing one hundred and two kilowatt hours of energy. A battery string 410A may contain greater or fewer numbers of battery modules 412A than depicted in the figures.

As the battery string 410A is a logical and electrical collection of battery modules 412A-N, the collection is not necessarily defined by the physical structure or ordering of the battery cells 412A-N, other than the constituent battery modules 412A-N in this example are wired in series. Therefore, the battery string 410A may be alternatively described as a battery rack, a battery sub-rack, or a battery array: each of these terms (element, rack, sub-rack, array) can be categories of battery string 410A: a battery string 410A is the logical and electrical collection of battery modules 412A-N, without explicit regard for physical structure or ordering of the battery modules 412A-N, other than in this particular example wiring in series. In some implementations, a finer level of encapsulation exists within the battery module 412A, which may be identified as a battery grouping within the battery module 412. Those battery groupings may also include a finer level of encapsulation, which may be identified as a battery cell within the battery grouping, comprising prismatic, pouch, or cylindrical battery cells.

In this example, the energy storage node 110A represents a single physical fixture, which may be limited in maximum size by the mass or volume a person, forklift, or vehicle is capable of transporting as a singular, atomic unit. The battery bank 413 within the battery module 110A represents a physical organizational structure for organizing and wiring battery cells, groupings, battery modules 412A-N, and battery strings 410A-F within the energy storage node 110A. A battery cell is generally the largest unit of manufacture a battery producer can produce capable of charging and discharging electricity at a chemical level. In some examples battery cells are packaged together as battery modules 412A-N, representing the smallest unit a particular operator would remove or replace in the battery energy storage system 100: in examples where a multiple battery cells are packaged together, the individual battery cells are too small or sensitive to perform on-site particularized maintenance, and instead the entire package of battery cells (e.g., a battery module 412A) is either collectively repaired or replaced.

The energy storage nodes 110A may resemble the features presented in the energy storage system described in International Application No. PCT/US2021/30551, filed on May 4, 2021, (published as WO201226011 on Nov. 11, 2021), titled “Energy Storage System with Removable, Adjustable, and Lightweight Plenums,” the entirety of which is incorporated by reference herein.

Generally, a current circuit, for example a 1500-volt direct current circuit during discharging, includes an inverter as well as at least one energy storage node. A current waveform of the current circuit may contain noise that can likely be attributed to the inverter, which often sends power to batteries in the form of pulses. High power digital pules are a powerful source of interference. Inverters can be classified by their output waveform: square wave inverters (basic and least efficient), modified sine wave inverters (an approximation to sine wave output), and true sine wave inverters. Any deviation from a true sine wave results in high-frequency harmonics being generated, which can be radiated into the surrounding components.

Noise emissions from inverters are generally reduced by shielding. Metal enclosures are common for inverters and some other equipment, which protects the exterior from electrical noise, but not the interior of the enclosure. Shielding individual cables can also reduce noise, such as cabling between battery modules within a battery rack, but the increased cost of shielded cabling over unshielded cabling may be unacceptable in certain scenarios.

Another method of shielding is to twist the outbound and the return cable together: the noise from the outbound cable is generally equal and opposite to that of the return cable, as they are experiencing the same waveform but face opposite directions. Thus, the noisy magnetic fields generated are of the same magnitude, but generated in opposite directions, and essentially cancel each other out. However, within an energy storage node, or a battery rack of an energy storage node, the outbound cable connecting each battery module to the next battery module in series would need to be twisted with the return cable in order to perform twist shielding over the entire battery rack of the energy storage node, which would increase design complexity, and may unacceptably increase costs and difficulty of usability and installation.

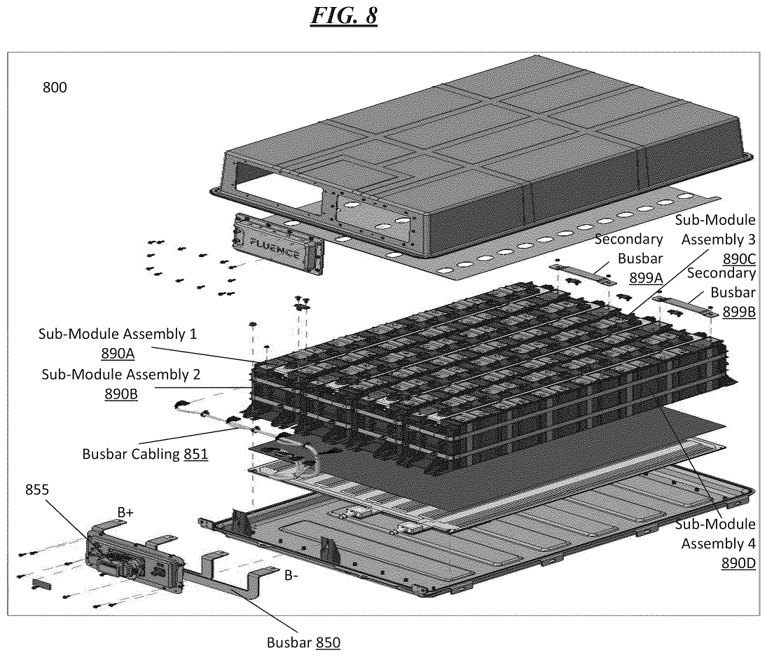

Embodiments of the invention provide a strategy of introducing one or more twists within each battery module minimal impact on cost, and in, for example, an eight-module battery rack, would introduce eight or a multiple of eight twists into the battery rack, which would have a noticeable impact on reducing noise radiated from the 1500-volt circuit within the enclosure of the energy storage node. The twists can be introduced to the busbar 850 (see FIG. 8) in order to cleanly introduce the twisting without requiring installation and maintenance technicians manually twist two cables together, and properly position the twisted cables on a plane with the return cable.

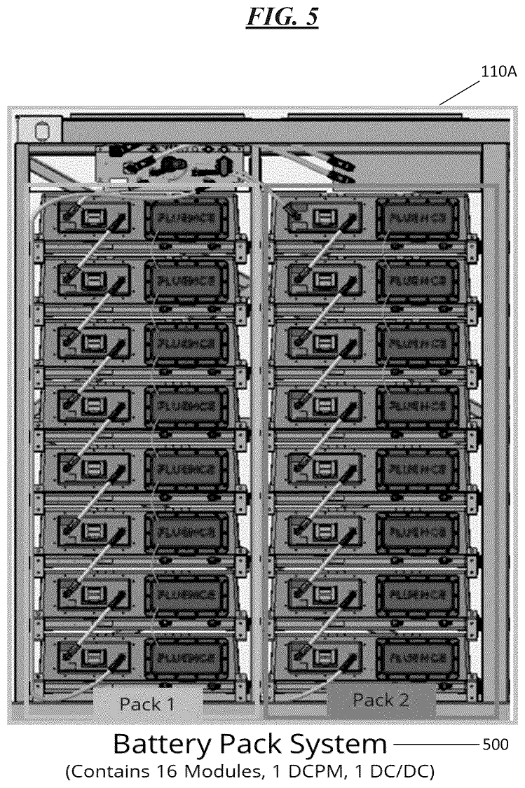

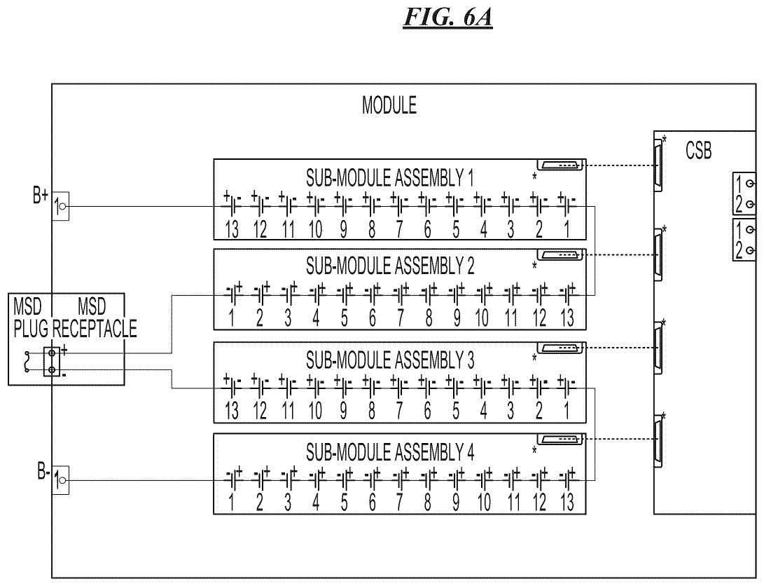

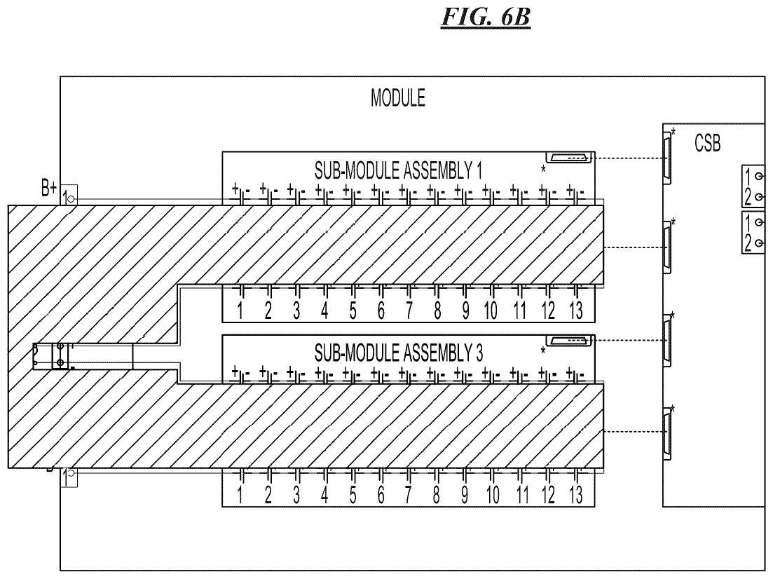

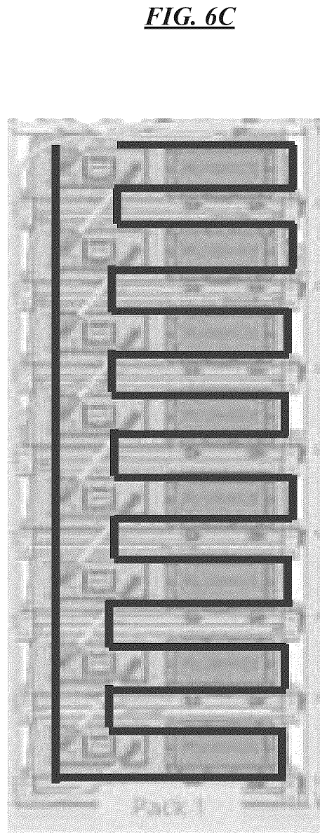

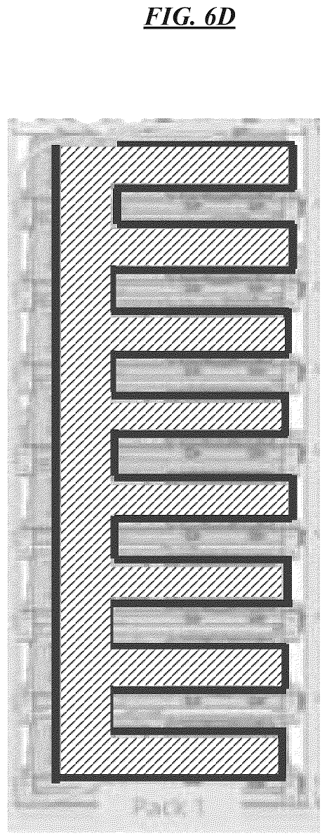

FIG. 5 is a general depiction of a battery pack system that may be arranged within an energy storage node. The battery pack system 500 includes, for example, a direct current power module (DCPM), a DC/DC converter, and two battery racks (Pack 1, Pack 2) each with eight battery modules. The battery rack labeled Pack 1 is, for example, a single battery rack which includes eight battery modules connected in series, and the rack labeled Pack 2 is also a single battery rack which includes additional battery modules connected in series. As shown in FIG. 6C, the eight battery modules arranged in a battery rack form a large loop with indentations on the right side, through the battery modules, resulting in a single large loop which then acts as a radiator or antenna to emit electromagnetic noise. The combination of energy storage nodes can be made up of multiple battery packs of modules arranged in accordance with system requirements, for example, four modules per pack or 8 modules per pack. As such, the invention is not limited to the arrangement of the exemplary battery pack system 500.

FIG. 6A is a depiction of a conventional battery module, and the direct current flow through the sub-module assemblies. The flow enters the module at battery cell 13 of sub-module assembly 1, passes through to battery cell 1 of sub-module assembly 1, connects to battery cell 13 of sub-module assembly 2, and passes through to battery cell 1 of sub-module assembly 2. Next, the flow passes into the manual service disconnect (MSD) receptacle, and if the MSD is not disconnected, the flow enters into and passes out of the MSD plug, and through the other side of the MSD receptacle. Next, the flow enters battery cell 13 of sub-module assembly 3, passes through to battery cell 1 of sub-module assembly 3, connects to battery cell 13 of sub-module assembly 4, and passes through to battery cell 1 of sub-module assembly 2, before exiting the module.

The entire flow of the module of FIG. 6A acts as a loop, with sub-module assembly 1 spaced from and not twisted with sub-module assembly 2, resulting in noise from the flow passing through sub-module 1 not materially cancelling the noise from the flow passing through sub-module 2; sub-module assembly 3 is also too far and not twisted with sub-module assembly 4, resulting in the noise from the flow passing through sub-module 3 not materially cancelling the noise from the flow passing through sub-module 4. Additionally, sub-module assembly 2 is too far and not twisted with sub-module assembly 3, resulting in the noise from the flow passing through sub-module 2 not materially cancelling the noise from the flow passing through sub-module 3.

FIG. 6B is a depiction of the conventional battery module of FIG. 6A having the electrical loop and noise area shaded. Even if the noise emitted by the flow through sub-module assembly 1 is cancelled by the noise emitted by the flow through sub-module assembly 2, and the noise emitted by the flow through sub-module assembly 3 is cancelled by the noise emitted by the flow through sub-module assembly 4, the segments between sub-module assembly 1 and 2, and between sub-module assembly 3 and 4 form a half of a loop, closed by the return cable which connects the module entry and exit. Therefore, the shaded area depicts the loop area formed within the battery module, which extends to the left beyond the edge of the battery module over to the return cabling which completes the circuit between the module entry and exit.

FIG. 6C is a depiction of a conventional battery rack, and the direct current flow through the battery modules. As the battery modules of FIG. 6A are connected in series, the flow through the entire battery rack is compiled into a single large loop having a substantial area.

FIG. 6D is a depiction of the conventional battery rack of FIG. 6C, with the electrical loop area shaded. The electrical loop covers a substantial cross-section of the battery rack, and acts as a single large radiator or antenna, emitting electromagnetic noise throughout the enclosure of the energy storage node. In high voltage scenarios, such as at 1500 volts, the electromagnetic noise is substantial, and puts sensitive electrical components at risk. Sensitive electrical components may be non-exhaustively found within the DCPM, or within the battery modules themselves. They may be related to power regulation, or safety, such as ventilators or flame retarders.

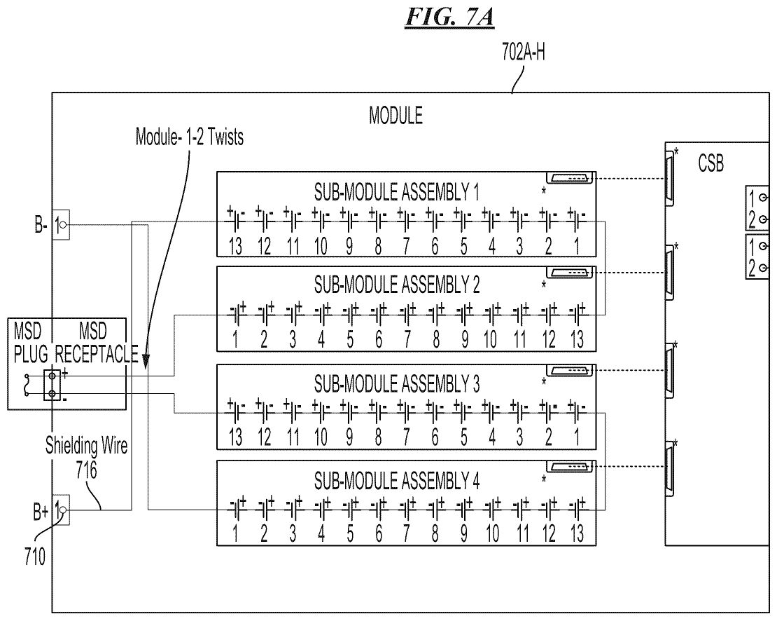

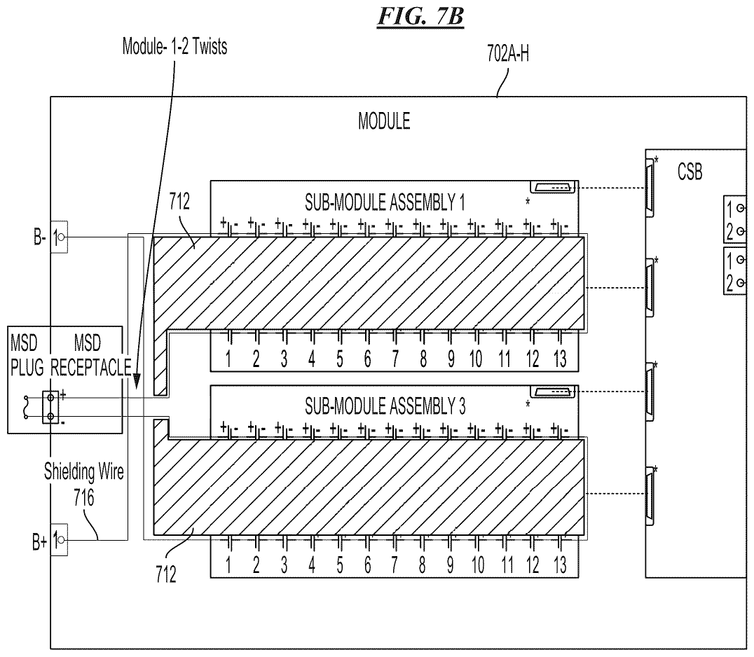

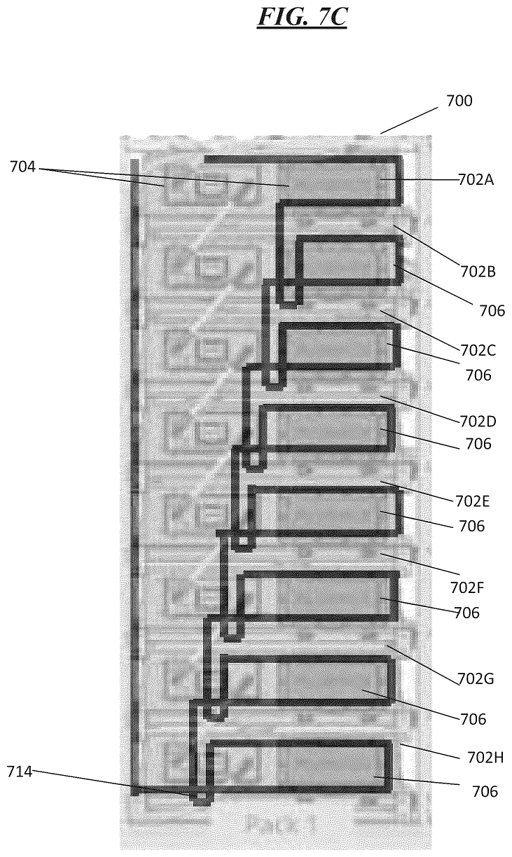

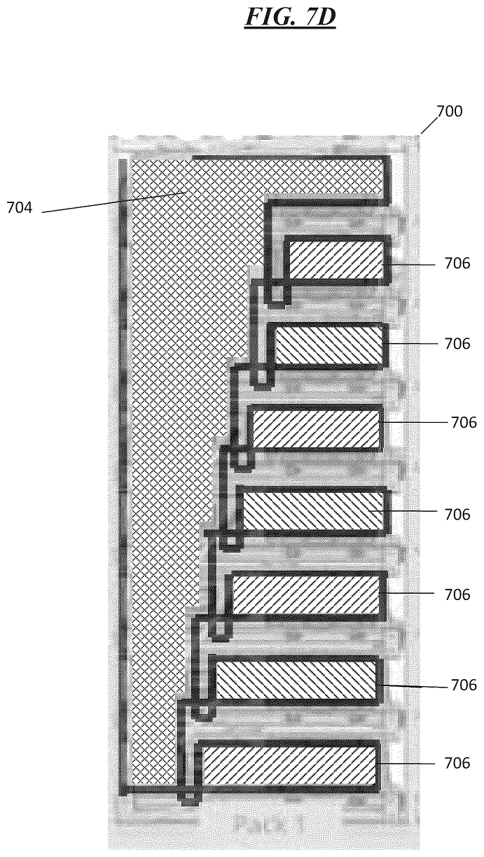

FIG. 7A illustrates an embodiment of a battery module implementing twists of the shielding wire 716, and the direct current flow through the sub-module assemblies. The flow enters the battery module 702A-H at the opposite end 710 of the module as compared to FIG. 6A, and immediately traverses a width of battery module 702A-H to enter battery cell 13 of sub-module assembly 1. The flow then passes through the sub-module assemblies in a similar manner as in FIG. 6A to flow through battery cell 1 of sub-module assembly 4, before again traversing the battery module, the shielding wire 716 twisting at least once with the first traversal section to form two shielded portions of the current flow, before exiting the module. In this example the entrance and exit are switched from the conventional design of FIG. 6A, while the sub-module assemblies flow in the same sequence: it is contemplated that the current flow entrance and exit may remain in the same location, while the sub-module assemblies are switched in terms of current flow direction. It is also contemplated that additional twists of the shielding wire 716 could be included elsewhere within the battery module, such as between sub-module assemblies or interleaved between battery cells of different sub-module assemblies. The shielded wire 716 twisted traversal flows may be implemented using a busbar configured to twist the two sections of current flow in the circuit together.

FIG. 7B illustrates the embodiment of the battery module of FIG. 7A having the separate electrical loop areas shaded 712. The entire flow through the battery module acts as a loop, but a closed loop. The area forming the loop in this example is not materially smaller, though the left face of the area terminates at the twisted traversal connections of the shielded wire 716, rather than at the return cable (as depicted in FIG. 6B). However, as the loop 712 is closed, it acts as a small individual loop radiator or antenna, rather than as a part of a larger loop radiator or antenna. Small loops have poor efficiency as antenna as compared to large loops, which is desirable in this setting: the “antenna” is broadcasting noise, not signal, and so an inefficient “antenna” will broadcast less noise than an efficient, large “antenna”, resulting in broadcasting less electromagnetic noise throughout the enclosure of the energy storage node.

FIG. 7C illustrates an embodiment of a battery rack 700 implementing an arrangement of battery modules 702A-H with wire twists 714, and the direct current flow through the battery modules. The twisted traversal sections 714 within each battery module 702A-H as illustrated, show the current flow passing against itself as it enters into each battery module of the rack 700.

FIG. 7D illustrates the embodiment of the battery rack 700 of FIG. 7C having the separate electrical loop areas 704, 706 shaded. Consequently, what was one large radiator loop in the related art of FIGS. 6C-D is now one medium-sized radiator loop 704 and several smaller radiator loops 706, as illustrated in the embodiment of FIGS. 7C-D. As radiator loop efficiency correlates to diameter and area, and the areas of each radiator loop is shrunken, the overall battery rack in FIGS. 7C-D is a less efficient “antenna” or radiator than the battery rack in FIGS. 6C-D, and therefore will provide a benefit to emit overall less electromagnetic noise into the enclosure of the energy storage node.

It should be noted that the internal busbars of the battery rack, or of the energy storage node 110A itself, may be twisted. Further, the connections between the energy storage node 110A and other energy storage nodes 110B-N can be twisted as well-any connection or cabling within the BESS 100 of FIGS. 1A and 1B can be twisted with itself or another section of connection or cabling to reduce electromagnetic emissions.

FIG. 8 is an exploded view diagram of an embodiment of a battery module 800 including a busbar arrangement. In the embodiment of FIG. 8, the battery module 800 includes sub-module assemblies 1-4 (890A-D), the MSD 855, the busbar 850, and the busbar cabling 851. The twists depicted in FIG. 7A can be introduced into the busbar 850 itself-a particularized busbar 850 could be used with parallel segments which are isolated to avoid a short-circuit. Doing so may make installation and maintenance easier, as the busbar 850 is rigid and inherently implements the twists in the current flow. The twists in the current flow of the battery module can also be introduced into the busbar cabling 851—doing so may further reduce cost as a particularized busbar 850 does not need to be obtained.

FIG. 8 further illustrates two smaller secondary busbars 899A-B which connect between sub-module assemblies 1 (890A) and 2 (890B) and sub-module assemblies 3 (890C) and 4 (890D). Twists may also be introduced to these secondary busbars 899A-B, and these secondary busbars 899A-B may be re-oriented, reconfigured, or extended to introduce twisting which reduces electromagnetic emissions. Alternatively, these secondary busbars 899A-B, in part due to their relatively short length, may be instead shielded to reduce electromagnetic emissions.

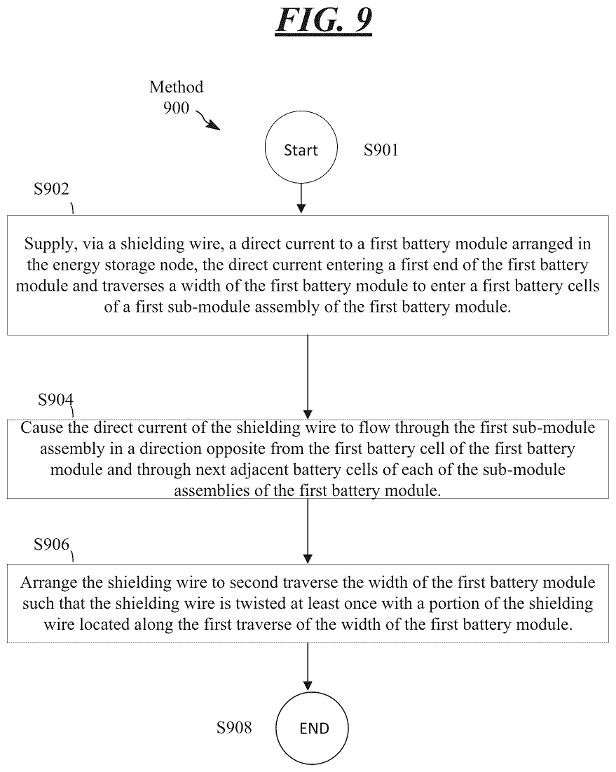

FIG. 9 illustrate a process flow 900 for lowering electromagnetic emissions inside an energy storage node. The process 900 begins at step S901 and moves to step S902. At step S902, a direct current is supplied 710 (see, FIGS. 7A and 7B) at a module via a shielding wire 716 to a first battery module of a plurality of battery modules 702A-H arranged within a rack 700 (see, FIGS. 7C and 7D) of an energy storage node 110A such as illustrated in FIGS. 1A and 1B. Each battery module of the plurality of modules 702A-H includes a plurality of sub-module assemblies 1-4. The direct current enters a first end 710 of the first battery module 702A-H via the shielding wire 716 and traverse a width of the first battery module to enter a first battery cell 13 of the sub-module assembly 1. The process then moves to step S904.

At step S904, the direct current of the shielding wire 716 flows through the first sub-module assembly 1 in a direction opposite from the first battery cell 13 to next adjacent battery cells (e.g., battery cells 12, 11, 10, 9, 8, . . . 1) of each sub-module assembly 1-4. The process then moves to step 906.

At step S906, after the direct current has flowed through the battery cells of each of the sub-module assemblies 1-4, the shielding wire 716 is arranged to second traverse the width of the battery module 702 such that the shieling wire 716 is twisted at least once at a portion 714 of the shielding wire located along the first traverse of the width of the battery module. An entire flow of the direct current through the battery modules 702A-H acts a closed loop having separate electrical loop areas 704, 706. The process moves to S908.

At step S908, the process ends with the separate electrical loops 704, 707 being formed by the twisted traversals and provide a result of lowering the electromagnetic emissions inside the energy storage node.

The battery energy storage system 100, energy storage nodes 110A, power conversion system 104, performance monitoring system element 105 and various controllers may rely on a processor. The processor serves to perform various operations, for example, in accordance with instructions or programming executable by the processor. Although the processor may be configured by use of hardwired logic, typical processors are general processing circuits configured by execution of programming. The processor can include elements structured and arranged to perform one or more processing functions, typically various data processing functions. Although discrete logic components could be used, the examples utilize components forming a programmable CPU. The processor for example includes one or more integrated circuit (IC) chips incorporating the electronic elements to perform the functions of the CPU. The processor, for example, may be based on any known or available microprocessor architecture, such as a Reduced Instruction Set Computing (RISC) using an ARM architecture, as commonly used today in mobile devices and other portable electronic devices. Of course, other processor circuitry may be used to form the CPU or processor hardware. Although the described examples of the processor each focus on only one microprocessor, for convenience, a multi-processor architecture can also be used. A digital signal processor (DSP) or field-programmable gate array (FPGA) could be suitable replacements for the processor but may consume more power with added complexity. The processor may also partially or fully comprise (1) a single board computer used for local computation, processing, and control of the battery energy storage system 100, energy storage nodes 110A, power conversion system 104, and various controllers; (2) an application-specific integrated circuit used for local computation, processing, and control of the battery energy storage system 100, energy storage nodes 110A, power conversion system 104, and various controllers; (3) other known distributed control system elements; or (4) a combination thereof.

A memory can be coupled to the processor. Memory devices are for storing data and programming. In the example, memory devices may include a flash memory (non-volatile or persistent storage) and/or a random-access memory (RAM) (volatile storage). The RAM serves as short term storage for instructions and data being handled by the processor e.g., as a working data processing memory. The flash memory typically provides longer term storage.

Of course, other storage devices or configurations may be added to or substituted for those in the example. Such other storage devices may be implemented using any type of storage medium having computer or processor readable instructions or programming stored therein and may include, for example, any or all of the tangible memory of the computers, processors or the like, or associated modules.

A network interface, like network interface 632 can be coupled to the processor. The network interfaces of the battery energy storage system 100, energy storage nodes 110A, power conversion system 104, performance monitoring system element 105, and various controllers are configured to communicate with one another

The scope of protection is limited solely by the claims that now follow. That scope is intended and should be interpreted to be as broad as is consistent with the ordinary meaning of the language that is used in the claims when interpreted in light of this specification and the prosecution history that follows and to encompass all structural and functional equivalents. Notwithstanding, none of the claims are intended to embrace subject matter that fails to satisfy the requirement of Sections 101, 102, or 103 of the Patent Act, nor should they be interpreted in such a way. Any unintended embracement of such subject matter is hereby disclaimed.

Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second, or evident and alternative, and the like may be used solely to distinguish one entity or action from another without necessarily requiring or implying any actual such relationship or order between such entities or actions. The terms “comprises,” “comprising,” “includes,” “including,” or any other variation thereof, are intended to cover a non-exclusive inclusion, such that a process, method, article, or apparatus that comprises or includes a list of elements or steps does not include only those elements or steps but may include other elements or steps not expressly listed or inherent to such process, method, article, or apparatus. An element preceded by “a” or “an” does not, without further constraints, preclude the existence of additional identical elements in the process, method, article, or apparatus that comprises the element.

In addition, in the foregoing Detailed Description, it can be seen that various features are grouped together in various examples for the purpose of streamlining the disclosure. This method of disclosure is not to be interpreted as reflecting an intention that the claimed examples require more features than are expressly recited in each claim. Rather, as the following claims reflect, the subject matter to be protected lies in less than all features of any single disclosed example. Thus, the following claims are hereby incorporated into the Detailed Description, with each claim standing on its own as a separately claimed subject matter.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present concepts.

What is claimed:

1. An energy storage node, comprising:
a plurality of battery modules arranged within the energy storage node; and
a shielding wire,
wherein each battery module of the plurality of battery modules includes a plurality of sub-module assemblies,
wherein a direct current supplied via the shielding wire enters a first battery module of the plurality of battery modules at a first end of the first battery module, wherein the shielding wire from the first end first traverses a width of the first battery module such that the direct current enters a first battery cell of a first sub-module assembly of the plurality of sub-module assemblies,
wherein the direct current of the shielding wire flows through the first sub-module assembly in a direction opposite from the first battery cell of the first sub-module assembly and through next adjacent battery cells of each of the plurality of sub-module assemblies of the first battery module,
wherein upon exiting a last of the plurality of sub-modules assemblies, the shielding wire is arranged to second traverse the width of the first battery module such that the shielding wire is twisted at least once with a portion of the shielding wire located along the first traverse of the width of the first battery module.

2. The energy storage node of claim 1, further comprising at least one bus bar arranged inside each of the plurality of battery modules of the energy storage node to support the shielding wire and connect to each sub-module assembly of the respective battery module.

3. The energy storage node of claim 2, further comprising at least two secondary busbars connected between adjacent sub-module assemblies of the first battery module.

4. The energy storage node of claim 1, wherein the shielding wire is a single cable configured between the plurality of battery modules and includes a plurality of twists located at a busbar of the battery module, wherein the plurality of twists of the shielding wire are arranged inside the battery module.

5. The energy storage node of claim 4, wherein a number of twists of the shielding wire within the plurality of battery modules of the energy storage node is an even number.

6. The energy storage node of claim 4, wherein a number of twists of the shielding wire within the plurality of battery modules of the energy storage node is at least eight.

7. The energy storage node of claim 4, wherein a number of the twists of the shielding wire within each battery module of the energy storage node is a multiple of eight.

8. The energy storage node of claim 1, wherein an entire flow of the direct current through each of the battery modules is a closed loop.

9. The energy storage node of claim 1, wherein the second traverse of the width of the first battery module is opposite a direction of the first traverse of the width of the first battery module.

10. A battery energy storage system, comprising a plurality of energy storage nodes of claim 1.

11. The battery energy storage system of claim 10, further comprising a power conversion system, a performance monitoring system element, and a controller.

12. A method for lowering electromagnetic emissions inside an energy storage node, the method comprising:
supplying, via a shielding wire, a direct current to a first battery module of a plurality of battery modules arranged in the energy storage node, wherein each battery module of the plurality of battery modules includes a plurality of sub-module assemblies,
wherein the direct current enters a first end of the first battery module via the shielding wire and traverses a width of the first battery module to enter a first battery cell of a first sub-module assembly of the plurality of sub module assemblies of the first battery module;
causing the direct current of the shielding wire to flow through the first sub-module assembly in a direction opposite from the first battery cell of the first battery module and through next adjacent battery cells of each of the other of the plurality of sub-module assemblies of the first battery module; and
arranging the shielding wire to second traverse the width of the first battery module such that the shielding wire is twisted at least once with a portion of the shielding wire located along the first traverse of the width of the first battery module.

13. The method of claim 12, further comprising arranging at least one bus bar inside each of the plurality of battery modules of the energy storage node to support the shielding wire and connect to each sub-module assembly of the respective battery module.

14. The method of claim 13, further comprising connecting at least two secondary busbars between adjacent sub-module assemblies of the first battery module.

15. The method of claim 12, wherein the shielding wire is a single cable configured between teach battery module of the plurality of battery modules of the energy storage node and includes a plurality of twists located at a busbar of the battery module, wherein the plurality of twists of the shielding wire are arranged within each respective battery module.

16. The method of claim 15, wherein a number of twists of the shielding wire with the plurality of battery modules is an even number.

17. The method of claim 15, wherein a number of twists of the shielding wire within the plurality of battery modules is at least eight.

18. The method of claim 14, wherein a number of twists of the shielding wire within each battery module is a multiple of eight.

19. The method of claim 12, wherein the shielding wire is arranged such that an entire flow of the direct current through each of the battery modules is a closed loop.

20. The method of claim 12, wherein the second traverse of the width of the first battery module is opposite a direction of the first traverse of the width of the first battery module.
